(19) United States
(12) Patent Application Publication
(10) Pub. No.: US 2008/0073761 A1
(43) Pub. Date: Mar. 27, 2008

(54) Semiconductor package and stacked semiconductor package

(75) Inventors: Chan-min Han, Hwaseong-si (KR); Beung-seuck Song, Incheon (KR); Sung-ki Lee, Cheonan-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/589,715

(22) Filed: Oct. 31, 2006

(30) Foreign Application Priority Data
Sep. 21, 2006 (KR) 10-2006-0091795

(51) Int. Cl. H01L 23/495

(52) U.S. Cl. 257/672; 257/787

(57) ABSTRACT

A semiconductor package including at least one semiconductor chip and inner leads may be provided. The semiconductor package may include a semiconductor chip. A plurality of inner leads having upper surfaces and lower surfaces, may be electrically connected to the semiconductor chip, and may be spaced apart from the semiconductor chip. A molding resin may fix the semiconductor chip and the inner leads. The upper surfaces of the inner leads may be fixed to the molding resin, the lower surfaces of the inner leads may be exposed from the molding resin, and widths of the lower surfaces of the inner leads may be narrower than widths of the upper surfaces of the inner leads.

### PRIORITY STATEMENT

This application claims the benefit of priority to Korean Patent Application No. 10-2006-0091795, filed on Sep. 21, 2006, in the Korean Intellectual Property Office, the entire contents of which is incorporated herein in its entirety by reference.

### BACKGROUND

1. Field

Example embodiments relate to a semiconductor device, and for example, to a semiconductor package and a stacked semiconductor package.

2. Description of Related Art

Assembling technology for manufacturing semiconductor packages has improved with the advancement of semiconductor device technology. For example, the size of semiconductor packages has been reduced with semiconductor products becoming more compact and/or lighter. A semiconductor product may require a higher capacity semiconductor package. A stacked semiconductor package or a multi-chip semiconductor package including a plurality of semiconductor chips may be used.

The degree to which the thickness of a conventional stacked semiconductor package may be reduced may be limited due to a thickness of a molding resin enclosing semiconductor chips in upper and lower semiconductor packages. Leads of each of the upper and lower semiconductor packages may protrude underneath the molding resin, and the thickness of the conventional stacked semiconductor package may be further increased.

To solve these problems, a conventional method of forming lower surfaces of leads of a semiconductor package to be parallel with a molding resin has been suggested. However, the leads may be exposed from the molding resin in the semiconductor package. If a force is applied to the leads, the leads may be easily separated from the molding resin.

A conventional method of forming notches at the leads may be used. However, portions of the leads at which the notches may be formed become thinner, and the leads may be bent. Accordingly, it may be difficult to perform wire bonding for connecting the leads to a semiconductor chip.

A stack structure of semiconductor packages may have a problem of lower reliability of an electrical connection between leads of upper and lower semiconductor packages. For example, a contact area between leads may be small, and particles may be interposed between the leads. In the upper and lower semiconductor packages of this stack structure, the leads may be formed using half etching. An etching depth may become too deep, and the stacked semiconductor package may be difficult to use as a multi-chip package including a plurality of semiconductor chips.

### SUMMARY

Example embodiments may provide a semiconductor package including a plurality of semiconductor chips and effectively fixed leads.

Example embodiments may provide a higher density stacked semiconductor package.

According to an example embodiment, a semiconductor package may include a semiconductor chip, a plurality of inner leads including upper surfaces and lower surfaces, electrically connected to the semiconductor chip, and spaced apart from the semiconductor chip, and a molding resin fixing the semiconductor chip and the inner leads, the upper surfaces of the inner leads are fixed to the molding resin, the lower surfaces of the inner leads are exposed from the molding resin, and widths of the lower surfaces of the inner leads are narrower than widths of the upper surfaces of the inner leads.

According to an example embodiment, the inner leads may include lower portions having widths narrowing toward the lower surfaces. The inner leads may further include upper portions having uniform widths.

According to an example embodiment, the semiconductor package may further include a chip mounting pad on which the semiconductor chip may be mounted, wherein a width of a lower surface of the chip mounting pad may be narrower than a width of an upper surface of the chip mounting pad.

According to an example embodiment, the semiconductor package may further include a plurality of outer leads connected to the inner leads and extending from the molding resin.

According to an example embodiment, there may be provided a semiconductor package including a plurality of semiconductor packages which may be sequentially stacked, each of the plurality of semiconductor packages may includes a semiconductor chip; a plurality of inner leads including upper surfaces and lower surfaces, electrically connected to the semiconductor chip, and spaced apart from the semiconductor chip; a molding resin fixing the semiconductor chip and the inner leads, the upper surfaces of the inner leads of each of the semiconductor packages may be fixed to the molding resin, the lower surfaces of the inner leads of each of the semiconductor packages may be exposed from the molding resin, and widths of the lower surfaces of the inner leads may be narrower than widths of the upper surfaces.

### BRIEF DESCRIPTION OF THE DRAWINGS

The above and/or other aspects and advantages will become more apparent and more readily appreciated from the following detailed description of example embodiments taken in conjunction with the accompanying drawings of which:

FIG. 1 is a cross-sectional view of a semiconductor package according to an embodiment;

FIG. 2 is an enlarged perspective view of inner leads of the semiconductor package illustrated in FIG. 1;

FIG. 3 is an enlarged perspective view illustrating a modification of an example embodiment of an inner lead of the semiconductor package illustrated in FIG. 1;

FIG. 4 is an enlarged perspective view of a chip mounting pad of the semiconductor package illustrated in FIG. 1;

FIG. 5 is a cross-sectional view of a semiconductor package according to an example embodiment;

FIG. 6 is a cross-sectional view of a semiconductor package according to an example embodiment;

FIG. 7 is a cross-sectional view of a stacked semiconductor package according to an example embodiment;

FIG. 8A is a cross-sectional view of lower portions of inner leads according to an example embodiment;

FIG. 8B is a cross-sectional view of lower portions of inner leads according to an example embodiment;

FIG. 8C is a cross-sectional view of lower portions of inner leads according to an example embodiment; and

FIG. 8D is a cross-sectional view of lower portions of inner leads according to an example embodiment.

### DETAILED DESCRIPTION OF EXAMPLE EMBODIMENTS

Example embodiments will now be described more fully with reference to the accompanying drawings. Embodiments may, however, be embodied in many different forms and should not be construed as being limited to the example embodiments set forth herein; rather, these embodiments are provided so that this disclosure will be thorough and complete, and will fully convey the scope to those skilled in the art. In the drawings, the thicknesses of layers and regions may be exaggerated for clarity.

It will be understood that when a component is referred to as being “on,” “connected to” or “coupled to” another component, it can be directly on, connected to or coupled to the other component or intervening components may be present. In contrast, when a component is referred to as being “directly on,” “directly connected to” or “directly coupled to” another component, there are no intervening components present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the example embodiments.

Spatially relative terms, such as “beneath,” “below,” “lower,” “above,” “upper” and the like, may be used herein for ease of description to describe one component or feature's relationship to another component(s) or feature(s) as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Reference will now be made to example embodiments, which are illustrated in the accompanying drawings, wherein like reference numerals refer to the like components throughout.

According to example embodiments, inner leads and outer leads may be defined separately. The inner leads may refer to leads or lead frame portions including surfaces attached to and fixed to a molding resin, and the outer leads may refer to leads or lead frame portions extending from the molding resin. Although the inner and outer leads may be defined separately, the inner and outer leads may refer to a structure body which may be virtually divided into inner and outer leads physically connected to one another. Accordingly, in example embodiments, a semiconductor package may include only inner leads or may include inner leads and/or outer leads.

According to example embodiments, a stacked semiconductor package may refer to a structure in which at least one or more semiconductor packages or at least one or more pairs of semiconductor packages may be stacked.

FIG. 1 is a cross-sectional view of a semiconductor package 100 according to an example embodiment. Referring to FIG. 100, the semiconductor package 100 may include a semiconductor chip 108 which may be fixed and/or protected by a molding resin 112. The semiconductor chip 108 may include a memory device and/or a logic device. However, example embodiments are not limited to this type of device. The molding resin 112 may protect the semiconductor chip 108 from the external environment and may include an epoxy compound.

A chip mounting pad 104 may include an upper surface 1041 and/or a lower surface 1042, and the semiconductor chip 108 may be adhered to the upper surface 1041 of the chip mounting pad 104 using an adhesive member 106. For example, the lower surface 1042 of the chip mounting pad 104 may be exposed from the molding resin 112. However, example embodiments are not limited thereto. In a modification of an example embodiment, the chip mounting pad 104 may be omitted, and the semiconductor chip 108 may be disposed and electrically connected to a plurality of inner leads 102. This structure may be called a lead-on-chip (LOC) structure. However, example embodiments are not limited thereto.

The inner leads 102 may be electrically connected to the semiconductor chip 108 by conductive wires 110 and/or fixed by the molding resin 112. The inner leads 102 may include upper surfaces 1021 connected to the wires 110 and lower surfaces 1022 opposite to the upper surfaces 1021. The upper surfaces 1021 of the inner leads 102 may be adhered to and/or fixed to the molding resin 112. The lower surfaces 1022 of the inner leads 102 may be exposed from the molding resin 112, and ends of the inner leads 102 may be exposed from the molding resin 112.

The exposed portions of the inner leads 102 may operate as external terminals or may be used as portions connected to another semiconductor package in a stack structure. The semiconductor package 100 may be called an exposed lead package (ELP) due to the structures of the inner leads 102. However, example embodiments are not limited thereto.

In the semiconductor package 100, the inner leads 102 need not extend upward the semiconductor chip 108. Accordingly, a space may be left above the semiconductor chip 108. The semiconductor package 100 may further include a plurality of semiconductor chips (not shown) stacked on the semiconductor chip 108. For example, the semiconductor package 100 may be easily modified into a multi-chip package (MCP).

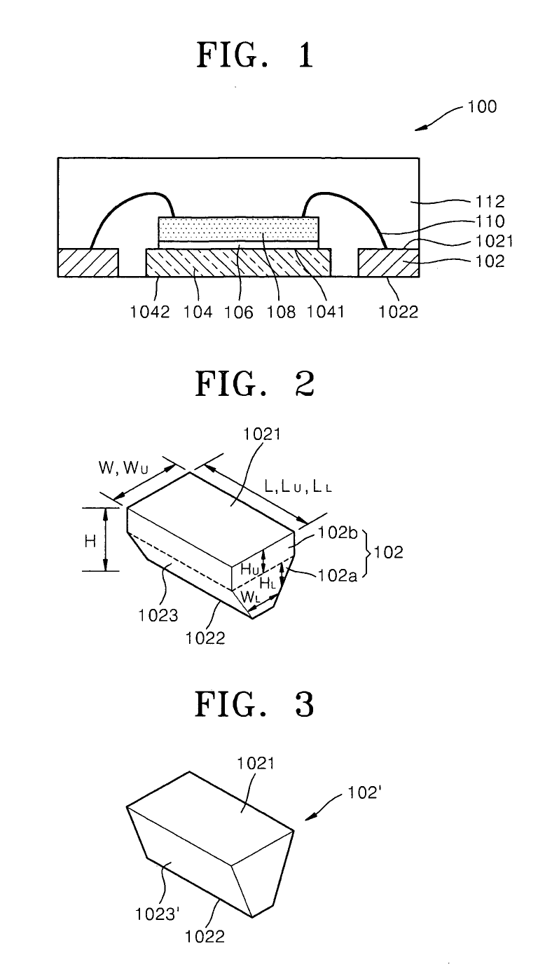

FIG. 2 is an enlarged perspective view of the inner leads 102 of the semiconductor package 100 illustrated in FIG. 1. The inner leads 102 may have variable heights H, variable widths W, and/or lengths L. Referring to FIG. 2, the inner leads 102 may include lower portions 102a and upper portions 102b. The lower portions 102a may have variable heights HL, variable widths WL, and/or lengths LL. The upper portions may have lengths Lu, widths Wu, and/or heights Hu. For example, widths WL of the lower portions 102a of the inner leads 102 may narrow toward the lower surfaces 1022, and widths of the Wu upper portions 102b may be uniform. Both sides 1023 of the inner leads 102 may be fixed by the molding resin 112. Both sides 1023 in the lower portions 102a of the inner leads 102 may be inclined. The inner leads 102 may extend to be distant from the semiconductor chip 108. For example, the inner leads 102 may be spaced apart from the semiconductor chip 108. Accordingly, widthwise directions W of the inner leads 102 may be perpendicular to directions toward which the inner leads 102 extend. These structures of the inner leads 102 may be formed using an etching method or a pressing method.

In the above-described structure, the inner leads 102 may be effectively fixed by the molding resin 112 because the molding resin 112 contacting or adhering to both sides 1023 of the inner leads 102 may protrude toward the lower surfaces of 1022 of the inner leads 102 due to the shape of the lower portions 102a of the inner leads 102. Although the inner leads 102 may receive a downward force, the inner leads 102 may be supported by the protruding portions of the molding resin 112 contacting both sides 1023. A force may be more uniformly distributed to the inner leads 102 than general local notches. The inner leads 102 need not be bent but fixed during bonding of the wires 110. The reliability of bonding between the wires 110 and the inner leads 10 may be improved.

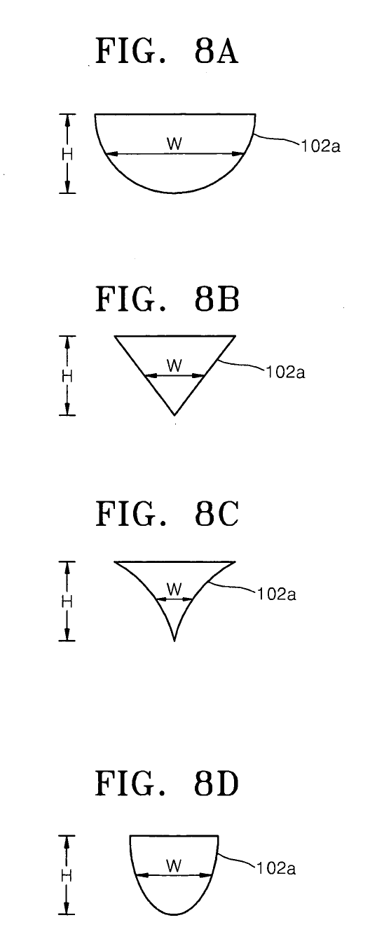

In example embodiments, the widths WL of the lower portions 102a of the inner leads 102 may narrow linearly. However, example embodiments are not limited thereto. If the inner leads 102 are formed using an etching method, the widths WL of the lower portions 102a of the inner leads 102 may be nonlinearly narrowed depending on etching conditions. The widths WL of the lower portions 102a of the inner leads 102 may be narrowed to be symmetrical based on both sides 1023. For example, the inner leads 102 may be effectively fixed by the molding resin 112 due to a symmetrical distribution of a force. However, example embodiments are not limited thereto. The widths of the lower portions 102a of the inner leads 102 may be nonlinearly narrowed. In example embodiments the lower portions 102a of the inner leads 102 may have half circle shapes as illustrated in FIG. 8A. In example embodiments the lower portions 102a of the inner leads 102 may have triangular shapes as illustrated in FIG. 8B. In example embodiments the lower portions 102a of the inner leads 102 may have inverse spacer shapes as illustrated in FIG. 8C. In example embodiments the widths of the lower portions 102a may have curved or parabolic shapes as illustrated in FIG. 8D.

A ratio between heights of the lower and upper portions 102a and 102b of the inner leads 102 may be appropriately controlled in consideration of a desired or fixed degree thereof. As the height HL of the lower portions 102a of the inner leads 102 is increased, the inner leads 102 may be further fixed by the molding resin 112, for example, the inner leads 102 may be more tightly fixed. However, the inner leads 102 may receive a greater load during the bonding of the wires 110. As shown in FIG. 3, the inner leads 102 need not include the upper portions 102b. Referring to FIG. 3, widths WL of inner leads 102′ may be narrowed toward lower surfaces 1022. For example, both sides 1023′ of the inner leads 102′ may be inclined, and a height of both sides 1023′ may be higher than a height of both sides 1023 of the inner leads 102 shown in FIG. 2.

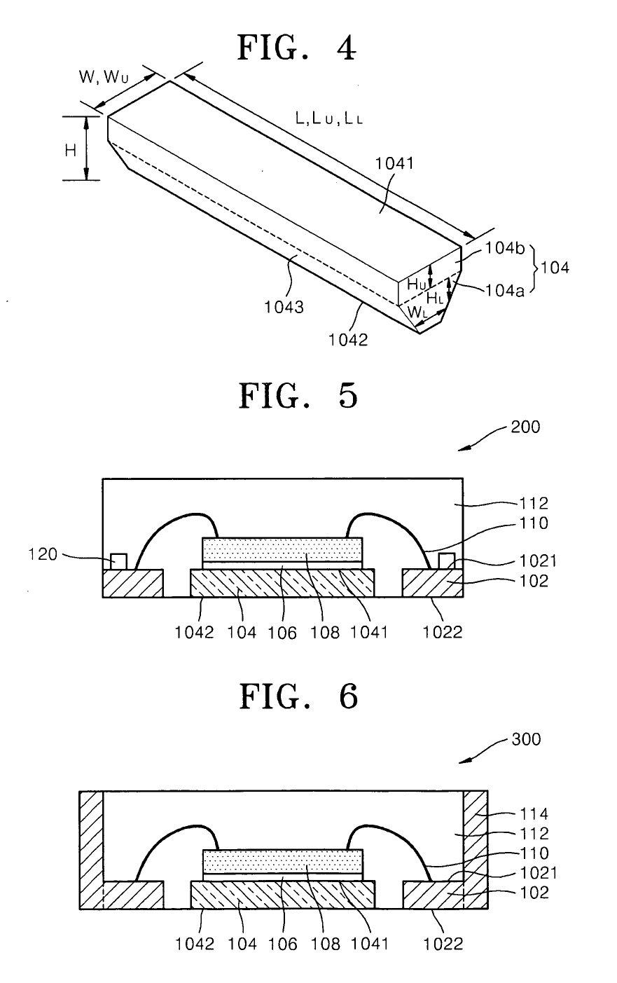

FIG. 4 is an enlarged perspective view of the chip mounting pad 104 of the semiconductor package 100 illustrated in FIG. 1. Referring to FIG. 4, the chip mounting pad 104 may include lower and/or upper portions 104a and 104b. The chip mounting pad may have variable widths W, variable heights H, and/or lengths L. The lower portions 104a may have variable widths WL and variable heights HL, and lengths L. The upper portions 104b may have widths Wu and heights Hu, and lengths L. For example, a width WL of the lower portion 104a of the chip mounting pad 104 may be narrower toward a lower surface 1042, and a width Wu of the upper portion 104b may be uniform. Both sides 1043 of the chip mounting pad 104 may be fixed by the molding resin 112. Both sides 1043 may be inclined to the lower portion 104a of the chip mounting pad 104. The structure of the chip mounting pad 104 may be formed using an etching method or a pressing method.

The structure of the chip mounting pad 104 may be similar to the above-described structures of the inner leads 102. The chip mounting pad 104 may be effectively fixed by the molding resin 112 because the molding resin contacting or adhering to both sides 1043 of the chip mounting pad 104 may protrude the lower surface 1042 of the chip mounting pad 104 due to a shape of the lower portion 104a of the chip mounting pad 104. Although the chip mounting pad 104 may receive a downward force, the chip mounting pad 104 may be supported by the protruding portions of the molding resin 112 contacting both sides 1043.

In example embodiments, the width WL of the lower portion 104a of the chip mounting pad 104 may narrow linearly. However, example embodiments are not limited thereto. If the chip mounting pad 104 is formed using an etching method, the width WL of the lower portion 104a of the chip mounting pad 104 may be nonlinearly narrowed depending on etching conditions. The width WL of the lower portion 104a of the chip mounting pad 104 may be narrowed to be symmetrical on both sides 1043. However, example embodiments are not limited thereto. In example embodiments the lower portion 104a of the chip mounting pad 104 may have a half circle shape similar to that of lower portions 102a of the inner leads 102 as illustrated in FIG. 8A. In example embodiments the lower portion 104a of the chip mounting pad 104 may have a triangular shape similar to that of lower portions 102a of the inner leads 102 as illustrated in FIG. 8B. In example embodiments the lower portion 104a of the chip mounting pad 104 may have an inverse spacer shape similar to that of lower portions 102a of the inner leads 102 as illustrated in FIG. 8C. In example embodiments the lower portion 104a of the chip mounting pad 104 may have a curved or parabolic shape similar to that of lower portions 102a of the inner leads 102 as illustrated in FIG. 8D.

A ratio between heights of the lower and upper portions 104a and 104b of the chip mounting pad 104 may be controlled according to a desired or fixed degree thereof. The upper portion 104b of the chip mounting pad 104 may be omitted as in the inner leads 102′ shown in FIG. 3.

FIG. 5 is a cross-sectional view of a semiconductor package 200 according to another example embodiment. The semiconductor package 200 may refer to the semiconductor package 100 shown in FIG. 1, and a detailed description thereof will be omitted herein.

Referring to FIG. 5, the semiconductor package 200 may further include nonconductive intermediate members 120. The nonconductive intermediate members 120 may be interposed between upper surfaces 1021 of inner leads 102 and a molding resin 112. The nonconductive intermediate members 120 may extend across at least portions of the inner leads 102. For example, the nonconductive intermediate members 120 may extend across the upper surfaces of the inner leads 102. In example embodiments the nonconductive intermediate members 120 may have a bar shape.

The inner leads 102 may be further fixed by the molding resin 112 due to the nonconductive intermediate members 120, for example the inner leads may be more tightly fixed, because the nonconductive intermediate members 120 may be disposed on portions of the molding resin 112 between the inner leads 102 and may be difficult to separate from the molding resin 112.

FIG. 6 is a cross-sectional view of a semiconductor package 300 according to another example embodiment. The semiconductor package 300 may refer to the semiconductor package 100 illustrated in FIG. 1, and a detailed description thereof will be omitted herein.

Referring to FIG. 6, the semiconductor package 300 may further include a plurality of outer leads 114. The outer leads 114 may be connected to inner leads 102 and may extend outside the molding resin 112. The outer leads 114 may extend from the inner leads 102 to operate as external terminals connecting the semiconductor package 300 to another semiconductor package or another product.

For example, the outer leads 114 may be physically connected to the inner leads 102 and oriented perpendicular or substantially perpendicular to the inner leads 102. However, example embodiments are not limited to a range of the outer leads 114. In a modification of an example embodiment, the outer leads 114 may linearly extend from the inner leads 102 and have a different shape. In another modification of an example embodiment, the semiconductor package 300 may further include nonconductive intermediate members 120 as shown in FIG. 5.

Widths of lower portions of the outer leads 114 may be narrower than widths of upper portions of the outer leads 114 as in the inner leads 102 illustrated in FIG. 2. The outer leads 114 may be modified into the shapes of the inner leads 102′ illustrated in FIG. 3. The outer leads 114 may be modified into the shapes illustrated in FIGS. 8A-8D. In a modification of an example embodiment, the widths of the lower portions of the outer leads 114 may be equal to the widths of the upper portions of the outer leads 114.

Because the outer leads 114 may not be disposed inside the molding resin 112, a height of the outer leads 114 may not be limited compared to when the outer leads 114 are formed using a half etching method. The semiconductor package 300 may further include a plurality of semiconductor chips (not shown) stacked on a semiconductor chip 108. For example, the semiconductor package 300 may be easily modified into a multi-chip package (MCP).

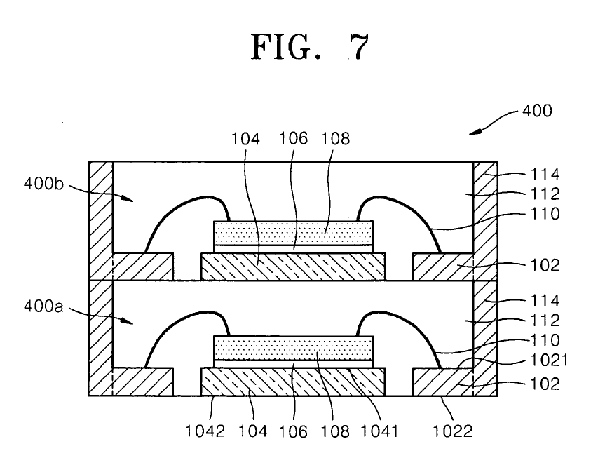

FIG. 7 is a cross-sectional view of a stacked semiconductor package 400 according to an example embodiment. Referring to FIG. 7, the stacked semiconductor package 400 may include lower and upper semiconductor packages 400a and 400b which may be stacked. For example, the upper and lower semiconductor packages 400b and 400a may be stacked sequentially. The lower and upper semiconductor packages 400a and 400b may refer to the semiconductor package 300 illustrated in FIG. 1, 5, and/or 6, and a detailed description thereof will be omitted herein. A semiconductor chip 108 of the lower semiconductor package 400a need not be equal in size to a semiconductor chip 108 of the upper semiconductor package 400b.

Outer leads 114 of the lower semiconductor package 400a may be electrically connected to outer leads 114 of the upper semiconductor package 400b. For example, edge portions of the outer leads 114 of the lower semiconductor package 400a may be connected to the outer leads 114 of the upper semiconductor package 400b using solder bonding. Molding resin 112 of the lower and upper semiconductor packages 400a and 400b of the stacked semiconductor package 400 may be directly adhered to each other. The stacked semiconductor package 400 may be manufactured at a higher density to have a smaller volume.

In a modification of an example embodiment, the outer leads 114 of the lower and upper semiconductor packages 400a and 400b may extend upward along sidewalls of the molding resin 112, and edge portions of the outer leads 114 may be oriented perpendicular to or substantially perpendicular to the molding resin 112. For example, the molding resin 112 of the lower semiconductor package 400a may be dented to place the edge portions of the outer leads 114 thereon so as to reduce the volume of the stacked semiconductor package 400. In other example embodiments, the edge portions of the outer leads 114 may be bent to contact the inner lead 102 of the upper semiconductor package 400b.

When the stacked semiconductor package 400 is mounted on a circuit board (not shown), the edge portions of the outer leads 114 and/or inner leads 102 of the lower semiconductor package 400a may contact wiring lines of the circuit board. A contact area may be increased to increase reliability of an electrical connection between the stacked semiconductor package 400 and the circuit board.

It has been described in example embodiments that the stacked semiconductor package 400 has the stack structure of the lower and upper semiconductor packages 400a and 400b. However, the stacked semiconductor package 400 of example embodiments may have a structure in which a plurality of semiconductor packages (not show) are further stacked.

Although example embodiments have been shown and described in this specification and figures, it would be appreciated by those skilled in the art that changes may be made to the illustrated and/or described example embodiments without departing from their principles and spirit, the scope of which is defined by the claims and their equivalents.

What is claimed is:

1. A semiconductor package comprising:
a semiconductor chip;
a plurality of inner leads including upper surfaces and lower surfaces, electrically connected to the semiconductor chip, and spaced apart from the semiconductor chip
a molding resin fixing the semiconductor chip and the plurality of inner leads,
wherein the upper surfaces of the plurality of inner leads are fixed to the molding resin, the lower surfaces of the plurality of inner leads are exposed from the molding resin, and widths of the lower surfaces of the plurality of inner leads are narrower than widths of the upper surfaces of the plurality of inner leads.

2. The semiconductor package of claim 1, wherein the plurality of inner leads extend distant from the semiconductor chip.

3. The semiconductor package of claim 1, wherein the plurality of inner leads include lower portions whose widths narrow toward the lower surfaces of the plurality of inner leads.

4. The semiconductor package of claim 1, wherein the plurality of inner leads include lower portions whose widths narrow symmetrically on both sides of the plurality of inner leads.

5. The semiconductor package of claim 3, wherein the lower portions of the plurality of inner leads narrow linearly.

6. The semiconductor package of claim 3, wherein the plurality of inner leads further include upper portions having uniform widths.

7. The semiconductor package of claim 1, wherein the plurality of inner leads narrow from the upper surfaces toward the lower surfaces.

8. The semiconductor package of claim 1, further comprising nonconductive intermediate members interposed between the upper surfaces of the plurality of inner leads and the molding resin.

9. The semiconductor package of claim 1, further comprising a chip mounting pad on which the semiconductor chip is mounted, wherein a width of a lower surface of the chip mounting pad is narrower than a width of an upper surface of the chip mounting pad.

10. The semiconductor package of claim 9, wherein the lower surface of the chip mounting pad is exposed from the molding resin.

11. The semiconductor package of claim 1, further comprising a plurality of outer leads connected to the plurality of inner leads and exposed from the molding resin.

12. The semiconductor package of claim 11, wherein the plurality of inner leads are physically connected to the plurality of outer leads.

13. The semiconductor package of claim 11, wherein widths of lower surfaces of the plurality of outer leads are narrower than widths of upper surfaces of the plurality of outer leads.

14. A stacked semiconductor package comprising:
a plurality of sequentially stacked semiconductor packages of claim 1.

15. The stacked semiconductor package of claim 14, wherein each of the plurality of semiconductor packages further includes a plurality of outer leads connected to the plurality of inner leads and exposed from the molding resin, wherein the plurality of inner leads of the plurality of semiconductor packages are connected to one another through the plurality of outer leads.

16. The stacked semiconductor package of claim 15, wherein the plurality of inner leads of the plurality of semiconductor packages are physically connected to the plurality of outer leads of the plurality of semiconductor packages.

17. The stacked semiconductor package of claim 15, wherein widths of lower surfaces of the plurality of outer leads of the plurality of semiconductor packages are narrower than widths of upper surfaces of the plurality of outer leads.

18. The stacked semiconductor package of claim 14, wherein the plurality of inner leads include lower portions whose widths narrow toward the lower surfaces of the plurality of inner leads.

19. The stacked semiconductor package of claim 18, wherein the plurality of inner leads include lower portions whose widths narrow symmetrically based on both sides of the plurality of inner leads.

20. The stacked semiconductor package of claim 18, wherein the lower portions of the plurality of inner leads narrow linearly.
